(19) United States
(12) Patent Application Publication
(10) Pub. No.: US 2010/0182303 A1
(43) Pub. Date: Jul. 22, 2010

(54) IMAGE DISPLAY DEVICE

(76) Inventors: Shinji Takasugi, Kanagawa (JP); Kohei Ebisuno, Kanagawa (JP)

Correspondence Address: BIRCH STEWART KOLASCH & BIRCH, PO BOX 747, FALLS CHURCH, VA, 22040-0747, US

(21) Appl. No.: 12/671,443

(22) PCT Filed: Jul. 29, 2008
(86) PCT No.: PCT/JP2008/063590

§ 371 Date: Jan. 29, 2010

(30) Foreign Application Priority Data
Jul. 30, 2007 (JP) 2007-197769

(51) Int. Cl. G09G 3/30; G06F 3/038

(52) U.S. Cl. 345/211; 345/55; 345/76

(57) ABSTRACT

According to one embodiment, an image display device includes: a plurality of pixels including a light-emitting element, a driver element that controls light emission of the light-emitting element, and a capacitive element electrically connected to the driver element; and an image signal line that is commonly connected to the pixels for sequentially supplying, to the pixels, an image signal corresponding to luminous brightness of the light-emitting element. The pixel includes a shield electrode that shields an electric field from the image signal line to the capacitive element.

### TECHNICAL FIELD

The present invention relates to an image display device such as an organic electroluminescence (EL) display device.

### BACKGROUND ART

There has conventionally been proposed an image display device employing a current control type organic EL element that has a function of generating light due to the recombination of a hole and an electron injected into a luminescent layer. As the image display device of this type, there has conventionally been known the one in which a pixel circuit including four thin film transistors (hereinafter referred to as TFT) made of amorphous silicon, polycrystalline silicon and so on, and an organic EL element formed of an organic light emitting diode and so on, forms one pixel (see, for example, Japanese Patent Application Laid-open No. 2006-209074). In the image display device disclosed in Japanese Patent Application Laid-open No. 2006-209074, a threshold voltage of a drive transistor which drives an organic EL element is detected, and a capacitive element that retains, in addition to the threshold voltage, the voltage which is needed to be applied to a gate electrode of the drive transistor so as to cause the organic EL element to emit light with a desired brightness is provided. With this configuration, a suitable current value is set to each pixel and the brightness of each pixel is controlled.

In an image display device of a sequential-writing system, one image signal line is shared by plural pixels. An image signal voltage corresponding to any one of pixels is always applied to the image signal line. When there is a parasitic capacitance between the image signal line and the capacitive element, the potential retained by the capacitive element varies due to the parasitic capacitance during a threshold-voltage detecting period for detecting the threshold voltage of each pixel or during a light-emitting period in which an organic EL element of each pixel emits light, whereby a problem arises such as the generation of crosstalk or ghost.

### DISCLOSURE OF INVENTION

### Problem To Be Solved By the Invention

The present invention aims to provide an image display device that can reduce crosstalk or ghost caused by a parasitic capacitance between an image signal line and a storage capacitance.

### Means For Solving Problem

An image display device according to one embodiment of the present invention comprises a plurality of pixels including: a light-emitting element; a driver element that controls light emission of the light-emitting element; and a capacitive element electrically connected to the driver element. The image display device comprises an image signal line that is commonly connected to the pixels for sequentially supplying, to the pixels, an image signal corresponding to luminous brightness of the light-emitting element. The pixel includes a shield electrode that shields an electric field from the image signal line to the capacitive element.

An image display device according to one embodiment of the present invention comprises: a plurality of pixels including a light-emitting element and a capacitive element for accumulating electrical charges corresponding to luminous brightness of the light-emitting element. The image display device comprises an image signal line that is commonly connected to the pixels, and the pixel further includes a shield electrode between the image signal line and the capacitive element.

### BRIEF DESCRIPTION OF DRAWINGS

FIG. 1 is a diagram illustrating one example of a configuration of a pixel circuit corresponding to one pixel in an image display device according to one embodiment of the present invention.

FIG. 2 is a plan view of the pixel circuit illustrated in FIG. 1.

FIG. 3 is a sectional view taken along a line A-A in FIG. 2.

FIG. 4-1 is a sectional view schematically illustrating one example of production procedure of one pixel circuit of the image display device (part 1).

FIG. 4-2 is a sectional view schematically illustrating one example of a production procedure of one pixel circuit of the image display device (part 2).

FIG. 4-3 is a sectional view schematically illustrating one example of a production procedure of one pixel circuit of the image display device (part 3).

FIG. 4-4 is a sectional view schematically illustrating one example of a production procedure of one pixel circuit of the image display device (part 4).

FIG. 4-5 is a sectional view schematically illustrating one example of a production procedure of one pixel circuit of the image display device (part 5).

FIG. 4-6 is a sectional view schematically illustrating one example of a production procedure of one pixel circuit of the image display device (part 6).

FIG. 5 is a top view of the pixel circuit in FIG. 4-1.

FIG. 6 is a diagram illustrating another example of a configuration of a pixel circuit corresponding to one pixel of the image display device.

FIG. 7 is a plan view of the pixel circuit in FIG. 6.

FIG. 8-1 is a diagram illustrating a configuration of a pixel circuit corresponding to one pixel in the image display device.

FIG. 8-2 is a diagram illustrating the pixel circuit in FIG. 8-1 having parasitic capacitances written therein.

FIG. 9 is a plan view illustrating one example of a pixel circuit in which the circuit diagram in FIG. 8 is actually realized.

FIG. 10 is a sectional view taken along a line A-A in FIG. 9.

FIG. 11 is a diagram illustrating one example of a control sequence for explaining a luminous control of the image display device.

### BEST MODE(S) FOR CARRYING OUT THE INVENTION

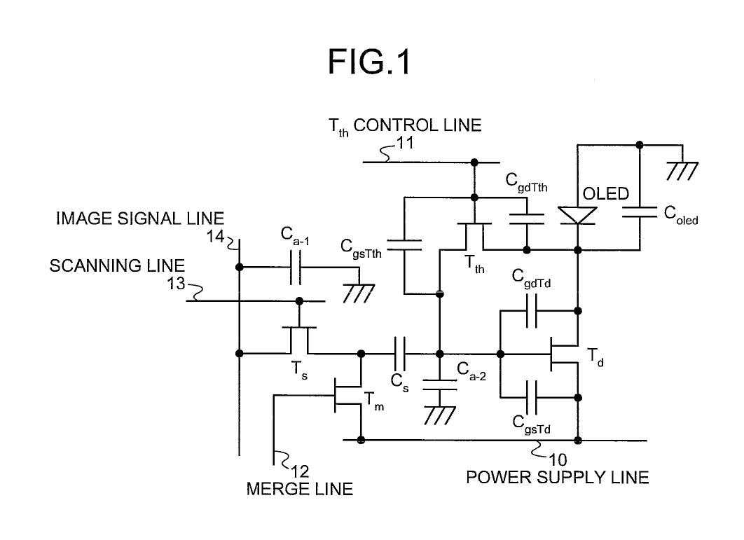

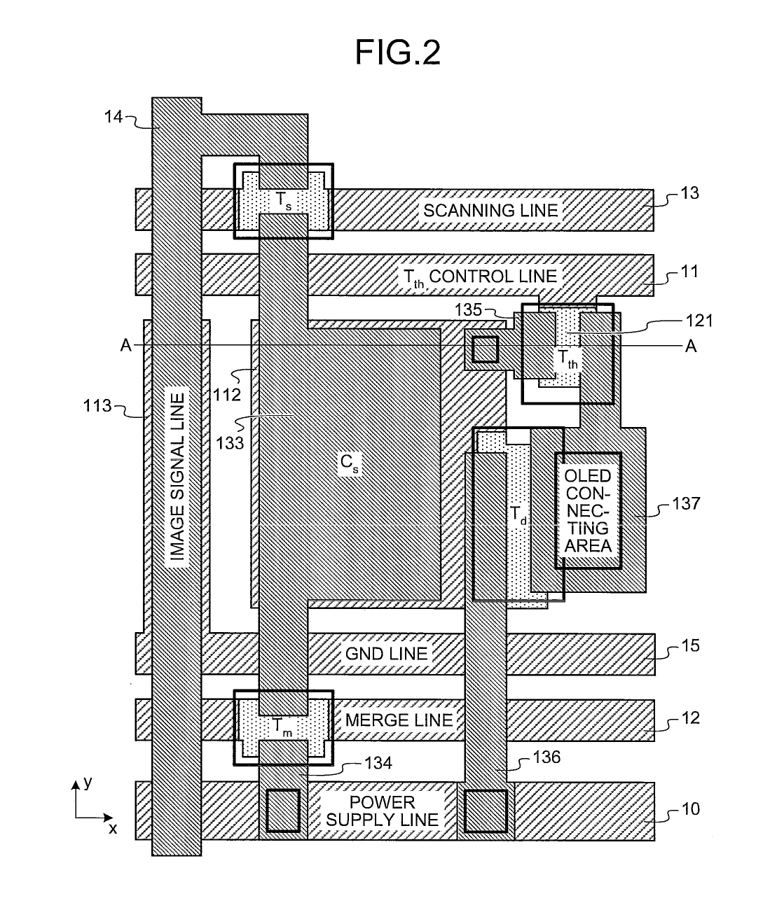

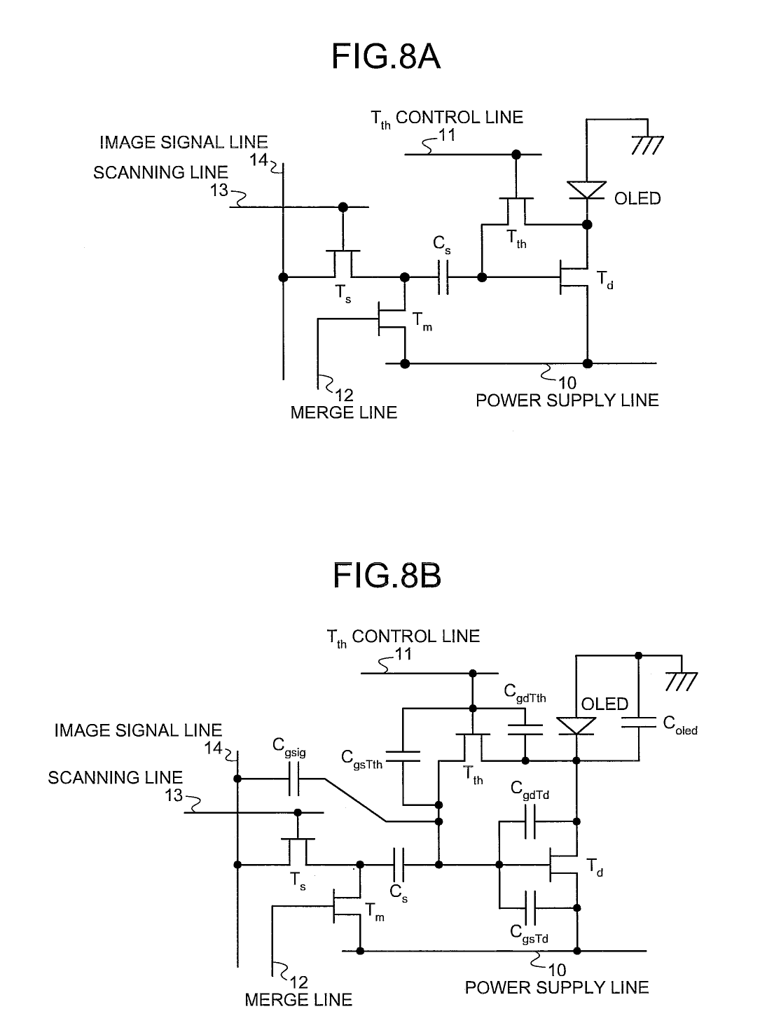

FIG. 8-1 is a circuit diagram for explaining a pixel circuit corresponding to one pixel in an image display device according to one embodiment of the present invention. FIG. 8-2 is a diagram in which parasitic capacitances are written in the pixel circuit illustrated in FIG. 8-1. The pixel circuit illustrated in FIG. 8-1 includes an organic EL element OLED, a drive transistor T_{d}, a threshold-voltage detecting transistor Tₜₕ, a storage capacitance Cₛ, a switching transistor Tₛ, and a switching transistor Tₘ.

The drive transistor T_{d} is a control element for controlling an amount of current flowing through the organic EL element OLED according to the potential difference applied between a gate electrode and a source electrode. The threshold-voltage detecting transistor Tₜₕ has a function of electrically connecting a gate electrode to a drain electrode of the drive transistor T_{d}, when the transistor Tₜₕ is turned on. The transistor T_{d} also has a function of detecting a threshold voltage Vₜₕ of the drive transistor T_{d} by flowing current from the gate electrode to the drain electrode of the drive transistor T_{d} until the potential difference between the gate electrode and a source electrode of the drive transistor T_{d} reaches the threshold voltage Vₜₕ of the drive transistor T_{d}.

The organic EL element OLED has a characteristic of emitting light since current flows due to the potential difference (potential difference between an anode and a cathode) of equal to or more than the threshold voltage. Specifically, the organic EL element OLED includes at least an anode layer and a cathode layer which are made of a conductive material, and a luminescent layer made of an organic material and formed between the anode layer and the cathode layer. Examples of the conductive material used for the anode layer and the cathode layer include Al, Cu, or ITO (Indium Tin Oxide). Examples of the organic material used for the luminescent layer include phthalocyanine, tris-aluminum complex, benzoquinolinolate, or beryllium complex. The organic EL element OLED has a function of emitting light due to the recombination of a hole and an electron injected into the luminescent layer.

The drive transistor T_{d}, the threshold-voltage detecting transistor Tₜₕ, the switching transistor Tₛ, and the switching transistor Tₘ are made of a thin film transistor, for example. In the respective drawings referred to below, the type (n-type or p-type) of the channel involved with each thin film transistor is not indicated specifically. However, the channel involved with each thin film transistor may be any of n-type and p-type, and it is in accordance with the description in the present specification.

A power supply line 10 supplies power from a power supply to the drive transistor T_{d} and the switching transistor Tₘ. A Tₜₕ control line 11 supplies a signal for controlling the threshold-voltage detecting transistor Tₜₕ. A merge line 12 supplies a signal for controlling the switching transistor Tₘ. A scanning line 13 supplies a signal for controlling the switching transistor Tₛ. An image signal line 14 supplies an image signal.

In FIG. 8-2, C_{gsTd} and C_{gdTd} indicate TFT parasitic capacitances of the drive transistor T_{d}, while C_{gsTth} and C_{gdTth} indicate TFT parasitic capacitances of the threshold-voltage detecting transistor Tₜₕ. C_{oled} indicates a capacitance of the organic EL element OLED, while C_{gsig} indicates a parasitic capacitance between the image signal line and the gate of the drive transistor T_{d}.

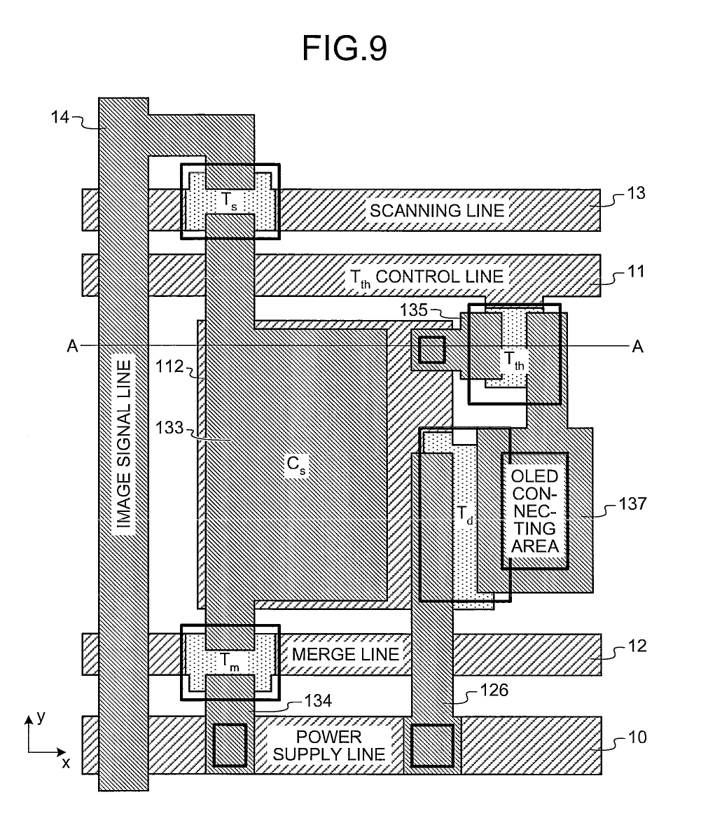

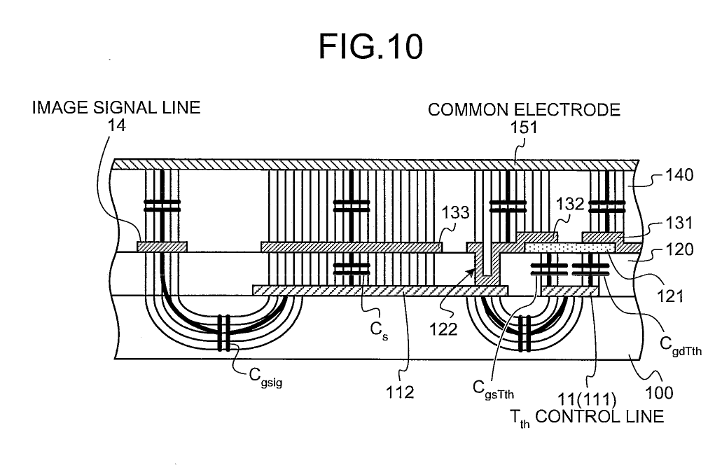

FIG. 9 is a plan view illustrating one example of a pixel circuit in which the circuit diagram in FIG. 8 is actually realized. FIG. 10 is a sectional view taken along a line A-A in FIG. 9. In FIG. 9, the lateral direction in the drawing is defined as x-axis direction, and the vertical direction in the drawing is defined as y-axis direction. In FIG. 10, the portion forming capacitance is illustrated with electrical lines of force.

A first wiring layer including a lower electrode 112, the power supply line 10, the Tₜₕ control line 11, the merge line 12, and the scanning line 13 of the storage capacitance Cₛ is formed onto a glass substrate 100 with a predetermined shape. The gate electrode of the drive transistor T_{d} is formed integral with the lower electrode 112 of the storage capacitance Cₛ. The gate electrode of the switching transistor Tₛ is formed integral with the scanning line 13. The gate electrode of the switching transistor Tₘ is formed integral with the merge line 12. The gate electrode of the threshold-voltage detecting transistor Tₜₕ is formed integral with the Tₜₕ control line 11.

A second wiring layer which includes the image signal line 14 or an upper electrode 133 of the storage capacitance Cs is formed on the first wiring layer with a predetermined shape with interposing an insulating layer 120. A third wiring layer which includes a common electrode 151 serving as an anode of the organic EL element OLED is formed on the second wiring layer with a predetermined shape with interposing a flattened film 140. The unillustrated organic EL element OLED is formed on the third wiring layer. The first and the second wiring layers, and the second and third wiring layers are electrically connected through contacts formed in via holes 122, respectively.

Specifically, the power supply line 10, the Tₜₕ control line 11, the merge line 12, and the scanning line 13 on the first wiring layer are formed parallel to the x-axis direction. The image signal line 14 of the second wiring layer is formed parallel to the y-axis direction. Here, the Tₜₕ control line 11 and the scanning line 13 are arranged parallel to each other on the positive direction side of the y axis, while the power supply line 10 and the merge line 12 are arranged parallel to each other on the negative direction side of the y axis. The drive transistor T_{d}, the threshold-voltage detecting transistor Tₜₕ, the storage capacitance Cₛ, and an OLED connecting area 137 are formed between the Tₜₕ control line 11 and the merge line 12. Notably, the drive transistor T_{d}, the threshold-voltage detecting transistor Tₜₕ, and the switching transistors Tₛ and Tₘ are composed of a TFT having a bottom gate structure.

A part of the lower electrode 112 arranged below the storage capacitance Cₛ is connected to the gate wiring of the drive transistor T_{d}. The source electrode of the drive transistor T_{d} is connected to the power supply line 10 through the wiring of the second wiring layer. The drain electrode is connected to the cathode of the unillustrated organic EL element OLED through the OLED connecting area 137 on the second wiring layer. The drain electrode of the threshold-voltage detecting transistor Tₜₕ is connected to the cathode of the unillustrated organic EL element OLED through the OLED connecting area 137 on the second wiring layer. The source electrode is connected to the lower electrode 112 of the storage capacitance Cₛ through a wiring 135 of the second wiring layer.

The gate electrode of the switching transistor Tₛ is composed of a part of the scanning line 13. The source electrode is connected to the image signal line 14 wired on the upper layer. The drain electrode is connected to the upper electrode 133 of the storage capacitance Cₛ of the second wiring layer. The gate electrode of the switching transistor Tₘ is formed commonly with the merge line 12. The source electrode is connected to the power supply line 10 through a wiring 134 of the second wiring layer. The drain electrode is connected to the upper electrode 133 of the storage capacitance Cₛ of the second wiring layer.

One of the anode electrode and the cathode electrode of the organic EL element OLED becomes a common electrode. In the circuit illustrated in FIG. 8-1, the anode electrode is the common electrode 151 serving as the ground potential. Since the wirings other than the common electrode 151 are overlapped with the common electrode 151, there are parasitic capacitances between the wirings and the common electrode 151. As illustrated in FIG. 8-2, the parasitic capacitances between the respective wirings other than the common electrode 151 are generated only at the side opposite to the common electrode 151 due to the electric-field shielding effect by the common electrode 151. Therefore, in FIG. 10, the parasitic capacitance C_{gsig} is generated between the image signal line 14 and the gate (=the lower electrode 112 of the storage capacitance Cₛ) of the drive transistor T_{d}.

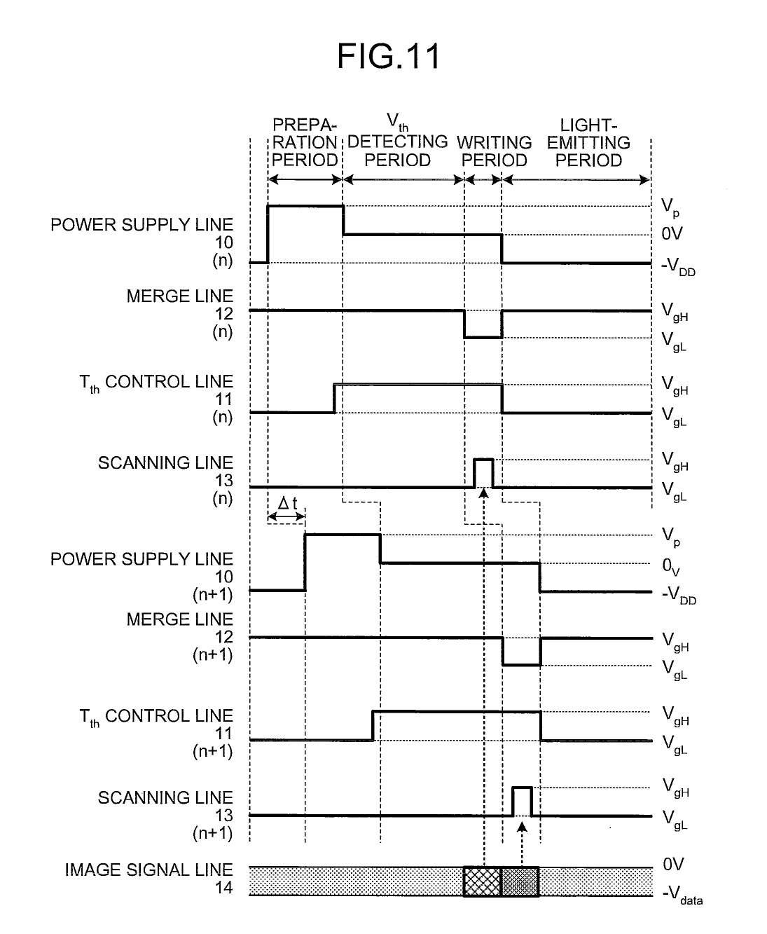

Next, the processing operation of the luminous control of the pixel circuit thus configured will be described. FIG. 11 is a view illustrating one example of a control sequence for describing the luminous control of the image display device. FIG. 11 illustrates the control sequence of the nth pixel circuit and (n+1)th pixel circuit connected to the common image signal line 14. As illustrated in FIG. 11, the pixel circuits are operated through four periods, namely a preparation period, a threshold voltage (Vₜₕ) detecting period, a writing period, and a light-emitting period. The image signal line 14 is shared with a plurality of pixel circuits arranged in line. Image signals are flown in the image signal line 14 in order that each pixel on the line emits light during the predetermined light-emitting period.

During the preparation period, the power supply line 10 is set to be high potential (Vₚ), the merge line 12 is set to be high potential (V_{gH}), the Tₜₕ control line 11 is set to be low potential (V_{gL}), and the scanning line 13 is set to be low potential (V_{gL}). Thus, the threshold-voltage detecting transistor Tₜₕ is turned off, the switching transistor Tₛ is turned off, the drive transistor T_{d} is turned on, and the switching transistor Tₘ is turned on. With this, current flows in the route of the power supply line 10→the drive transistor T_{d}→the organic EL element capacitance C_{oled}, whereby electrical charges are accumulated in the organic EL element capacitance C_{oled}. The reason why the electrical charges are accumulated on the organic EL element during this preparation period is for temporarily supplying current to the drive transistor T_{d} in order to detect the driving threshold value.

During the threshold-voltage detecting period, the power supply line 10 is set to be zero potential, the merge line 12 is set to be high potential (V_{gH}), the Tₜₕ control line 11 is set to be high potential (V_{gH}), and the scanning line 13 is set to be low potential (V_{gL}). Thus, the threshold-voltage detecting transistor Tₜₕ is turned on, whereby the drain and the gate of the drive transistor T_{d} is connected. The electrical charges accumulated in the storage capacitance Cₛ and the organic EL element capacitance C_{oled} are discharged, whereby current flows in the route of the drive transistor T_{d}→the power supply line 10. When the potential difference V_{gs} between the gate and the source of the drive transistor T_{d} reaches the threshold voltage Vₜₕ, the drive transistor T_{d} is turned off and the threshold voltage Vₜₕ of the drive transistor T_{d} is detected.

During the writing period, the data potential (−V_{data}) from the image signal line 14 is indirectly or directly supplied to the storage capacitance Cₛ, whereby the gate potential of the drive transistor T_{d} is shifted to a desired potential variably. Specifically, the power supply line 10 is set to be zero potential, the merge line 12 is set to be low potential (V_{gL}), the Tₜₕ control line 11 is set to be high potential (V_{gH}), the scanning line 13 is set to be high potential (V_{gH}), and the image signal line 14 is set to be the predetermined data potential (−V_{data}). Thus, the switching transistor Tₛ is turned on, while the switching transistor Tₘ is turned off. The electrical charges accumulated in the organic EL element capacitance C_{oled} are discharged and current flows in the route of the organic EL element capacitance C_{oled}→the threshold-voltage detecting transistor Tₜₕ→the storage capacitance Cₛ. As a result, the electrical charges are accumulated in the storage capacitance Cₛ. In other words, the electrical charges accumulated in the organic EL element capacitance C_{oled} move to the storage capacitance Cₛ.

During the light-emitting period, the power supply line 10 is set to be minus potential (−V_{DD}), the merge line 12 is set to be high potential (V_{gH}), the Tₜₕ control line 11 is set to be low potential (V_{gL}), and the scanning line 13 is set to be low potential (V_{gL}). Thus, the drive transistor T_{d} is turned on, the threshold-voltage detecting transistor Tₜₕ is turned off, and the switching transistor Tₛ is turned off. Therefore, current I_{ds} flows in the route of the organic EL element OLED→the drive transistor T_{d}→the power supply line 10. As a result, the organic EL element OLED emits light.

Here, the gate potential of the drive transistor T_{d} to the source on light emitting is defined as V_{gs}, and a and d are defined as constants. Thus, V_{gs} is expressed by the following equation (1). The current I_{ds} flowing through the drive transistor T_{d} is expressed by the following equation (2) using the equation (1).

$$\begin{matrix}{V}_{gs} = {V}_{th} + a \cdot {V}_{data} + d & ( 1 ) \\ \begin{matrix}{I}_{ds} = ( β / 2 ) {( {V}_{gs} - {V}_{th} )}^{2} \\ = ( β / 2 ) {( a \cdot {V}_{data} + d )}^{2}\end{matrix} & ( 2 )\end{matrix}$$

Since the brightness of the OLED is substantially in proportion to the current density, a desired brightness can be applied to each pixel through the control of the data potential (V_{data}) of the image signal line 14 as described above. The described process of the pixel circuit n in the periods from the preparation period to the light-emitting period is performed for the pixel circuit n+1 at the time shifted by a predetermined time Δt.

The potential of the image signal line 14 is set to be a potential for writing image data to the other pixels during the period other than the period of writing the own pixel. Since the parasitic capacitance C_{gsig} is generated between the image signal line 14 and the lower electrode 112 of the storage capacitance Cₛ (FIG. 10), the amount of electrical charges retained in the storage capacitance Cₛ at the time of completing the detection of Vₜₕ during the threshold-voltage detecting period is affected by the potential of the image signal line 14 through the parasitic capacitance C_{gsig}. As a result, the Vₜₕ detection potential is affected by the image data (the potential of the image signal line 14) of a line apart by a predetermined number of lines, so that it is visually recognized as ghost apart by the predetermined number of lines.

The potential of the gate of the drive transistor T_{d} while emitting light in the light-emitting period varies when the potential of the image signal line 14 varies because it is affected by the potential variation of the image signal line 14 through C_{gsig}. Therefore, when a bright graphic or dark graphic is displayed, it is visually recognized as crosstalk in which the lines corresponding to the graphic become bright or dark. Since the wirings other than the image signal line 14 are sequentially driven, the affect by the parasitic capacitance is even for all pixels and the visible bright difference is not generated.

In view of this, an image display device that can suppress the parasitic capacitance C_{gsig} between the image signal line 14 and the gate electrode of the drive transistor T_{d} (storage capacitance Cₛ) and its production method will be described in the embodiment described below.

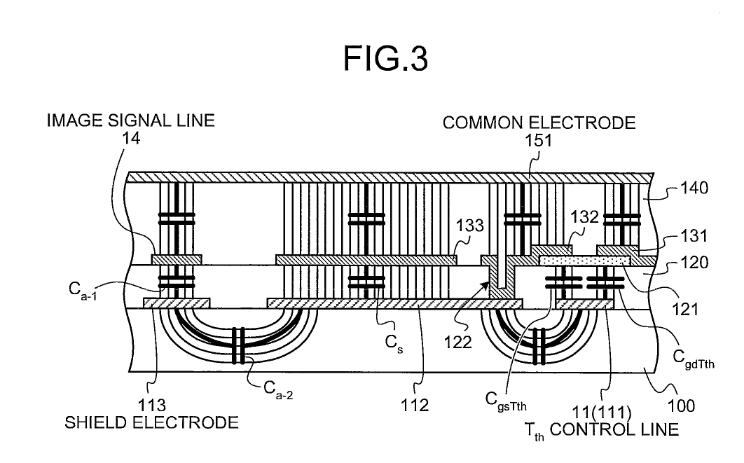

FIG. 1 is a circuit diagram illustrating a configuration of a pixel circuit corresponding to one pixel of the image display device according to one embodiment of the present invention. FIG. 2 is a plan view of the pixel circuit shown in FIG. 1, while FIG. 3 is a sectional view taken along a line A-A in FIG. 2. FIG. 1 also illustrates the parasitic capacitances generated between the respective electrodes or respective wirings. In FIG. 2, the lateral direction in the drawing is defined as x-axis direction, while the vertical direction in the drawing is defined as y-axis direction. The pixel circuit illustrated in FIG. 2 includes an organic EL element OLED serving as a light-emitting element, a drive transistor T_{d} serving as a driver element, a threshold-voltage detecting transistor Tₜₕ serving as a threshold voltage detecting element, a storage capacitance Cₛ serving as a capacitive element, and switching transistors Tₛ and Tₘ. In these drawings, the components same as those in FIGS. 8-1 to 11 are identified by the same numerals, and the description thereof will not be repeated.

The pixel circuit illustrated in FIGS. 1 to 3 also has a shield electrode 113 for shielding an electric field between the image signal line 14 and the storage capacitance Cₛ. Specifically, the electric field above the image signal line 14 is shielded by the common electrode 151. Therefore, the shield electrode 113 is provided in order to similarly shield the electric field below the image signal line 14. It is preferable that the shield electrode 113 is formed to be thicker than the width of the image signal line 14, and is arranged such that the image signal line 14 settles within the shield electrode 113 as viewed in the plane. According to this configuration, the electric field that can be generated between the image signal line 14 and the storage capacitance Cₛ can be shielded well. The specific width of the shield electrode 113 is preferably set to be greater than the width of the image signal line 14 by 1 to 3 μm. When the width of the shield electrode 113 is set to be greater than the width of the image signal line 14 by 1 μm or more, the image signal line 14 can be arranged so as to more surely settle within the shield electrode 113. When the width of the shield electrode 113 is set to be greater than the width of the image signal line 14 by 1 μm or more, protruding portions of the shield electrode 113 from the image signal line 14 by 0.5 μm or more are formed as viewed in the plane, whereby the leaked electric field also can be shielded. As a result, the effect of shielding the electric field between the image signal line 14 and the storage capacitance Cₛ can be more enhanced. In addition, the area where the lower electrode 112 or the like of the storage capacitance Cₛ is formed is widened. It is preferable that the width to be widened is not more than 3 μm. The shield electrode 113 is not a floating electrode, but has to be connected to any one of the wirings. If the shield electrode 113 is the floating electrode, the parasitic capacitance C_{gsig} increases and then crosstalk or ghost may occur. It is preferable that the shield electrode 113 is connected to the wiring whose potential does not vary all over the periods from the preparation period to the light-emitting period of the own pixel (own pixel circuit), i.e., specifically connected to the common electrode 151 (in this embodiment, the anode) that is the ground potential of the organic EL element OLED. However, when it is difficult to connect the shield electrode 113 to the wiring described above, it may be connected to the wiring whose potential is held substantially constant during each of the threshold-voltage detecting period and the light-emitting period. Examples of the wiring include the power supply line 10, the Tₜₕ control line 11, the merge line 12, and the scanning line 13 of the own pixel circuit that have little potential variation in the threshold-voltage detecting period and the light-emitting period of the own pixel circuit as illustrated in FIG. 11. Therefore, the shield electrode 113 can be connected to any one of these lines. Among these lines, the preferable line is the one having less voltage variation also in the periods other than the threshold-voltage detecting period and the light-emitting period.

In the pixel circuit illustrated in FIG. 2, compared to the pixel circuit illustrated in FIG. 9, the shield electrode 113 with the width greater than the line width of the image signal line 14 is formed below the image signal line 14. The shield electrode 113 is connected to a grounding line (hereinafter referred to as GND line) 15 extending in the x-axis direction. The GND line 15 is formed between the merge line 12 and the storage capacitance Cₛ, and is connected to the common electrode 151 (anode) that is retained to the GND potential through a contact at the unillustrated outside of the pixel circuit (pixel area) of the image display device.

As illustrated in FIG. 3, since the shield electrode 113 is formed below the image signal line 14, the generation of the parasitic capacitance C_{gsig} between the image signal line 14 and the lower electrode 112 of the storage capacitance Cₛ can be restricted. The shield electrode 113 forms a capacitance Cₐ₋₁ with the image signal line 14, while forms a capacitance Cₐ₋₂ with the gate line of the drive transistor T_{d} (the lower electrode 112 of the storage capacitance Cₛ).

Since the image display device adopts a sequential-writing system and the image signal line 14 is shared by each pixel, the image signal of the other pixel is supplied to the image signal line 14 during the period other than the writing period of the own pixel. However, since the shield electrode 113 is provided so as to shield the electric field between the image signal line 14 and the lower electrode 112 of the storage capacitance Cₛ, the storage capacitance Cₛ can decrease the effect caused by the potential of the image signal line 14 even in the threshold-voltage detecting period and the light-emitting period.

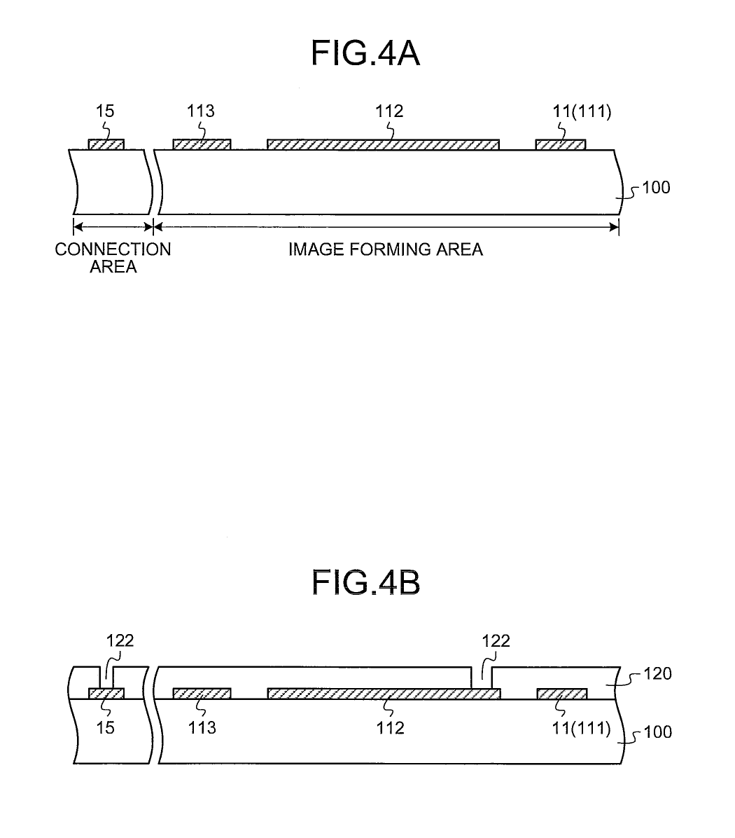

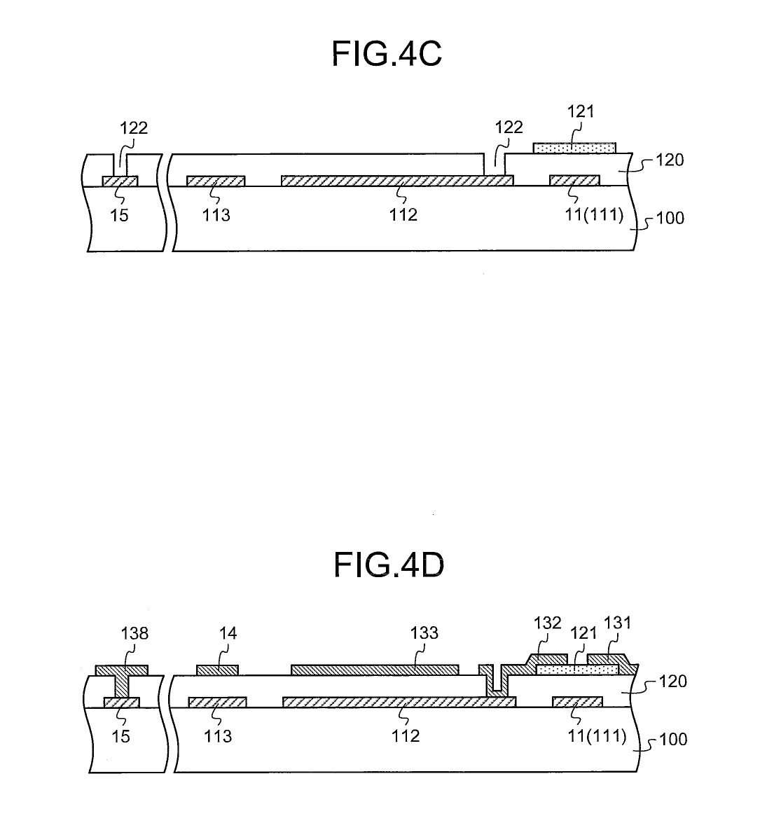

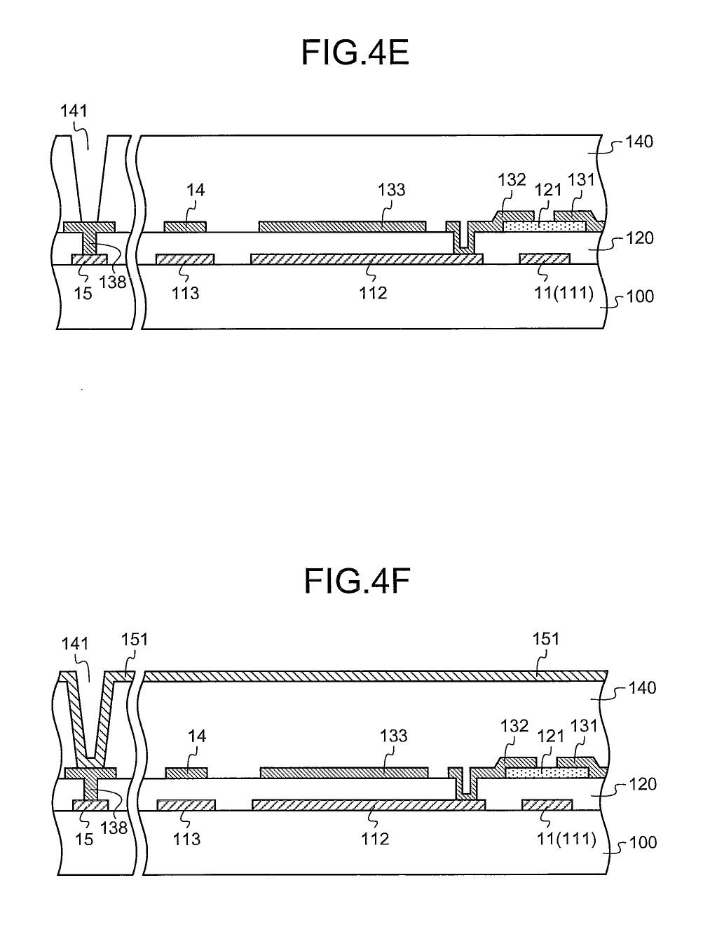

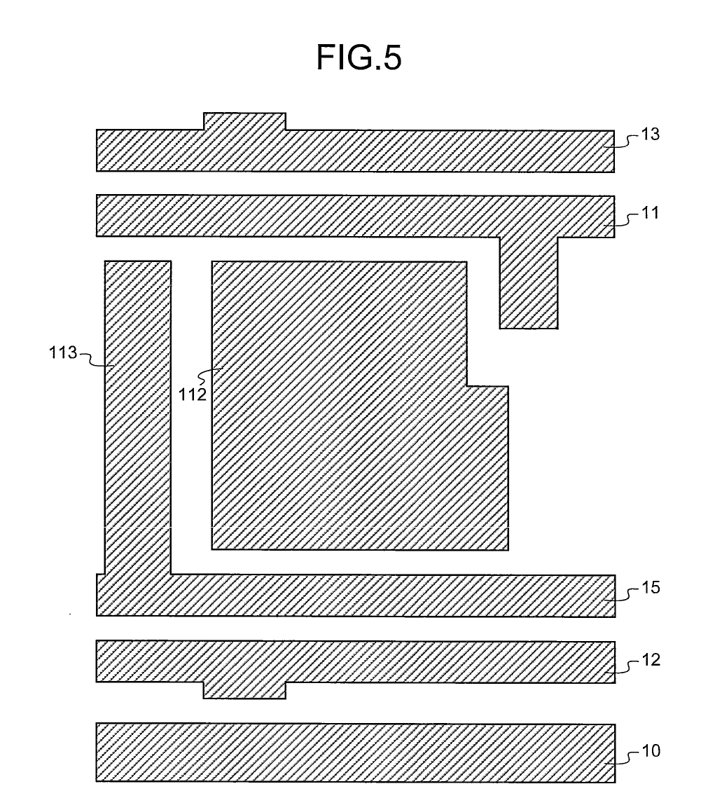

The method of producing the image display device having the configuration illustrated in FIGS. 1 to 3 will be described. FIGS. 4-1 to 4-6 are sectional views schematically illustrating one example of a production procedure of one pixel circuit of the image display device according to the present invention. FIG. 5 is a top view of the pixel circuit in FIG. 4-1. FIGS. 4-1 to 4-6 illustrate the sectional view of the area corresponding to the A-A line in FIG. 2 (hereinafter referred to as a pixel forming area), and the sectional view of the area in the vicinity of the connecting portion of the shield electrode and the common electrode that is not shown in FIG. 1 (hereinafter referred to as a connection area).

Firstly, a first conductive film, such as a metal, serving as a wiring is formed on the glass substrate 100. Then, the first conductive film is patterned into a predetermined shape by a photolithography technique and an etching technique so as to form a first wiring layer. The first wiring layer includes the drive transistor T_{d}, the gate electrodes of the switching transistors Tₛ and Tₘ, the lower electrode 112 of the storage capacitance Cₛ, the power supply line 10, the Tₜₕ control line 11 (gate electrode 111 of the threshold-voltage detecting transistor Tₜₕ), the merge line 12, the scanning line 13, and the shield electrode 113 (FIG. 4-1).

The gate electrode of the switching transistor Tₘ and the merge line 12 are integrally connected and formed. The gate electrode of the threshold-voltage detecting transistor Tₜₕ and the Tₜₕ control line 11 are integrally connected and formed. Further, the gate electrode of the drive transistor T_{d} and the lower electrode 112 of the storage capacitance Cₛ are integrally connected and formed. In order to connect the shield electrode 113 to the common electrode 151 of the OLED at the outside of the pixel area, the GND line 15 is formed from the shield electrode 113 to the connecting portion of the shield electrode 113 and the common electrode 151 (FIG. 5).

Then, the insulating layer 120 having a predetermined thickness is formed on the glass substrate 100 on which the first wiring layer has been formed. Via holes 122 that penetrate the insulating layer 120 are formed through the photolithography technique and etching technique in order to electrically connect second wiring layer to be formed later and the first wiring layer (FIG. 4-2). Thereafter, a channel layer 121 is formed on the areas where the drive transistor T_{d}, the switching transistors Tₛ and Tₘ, and the threshold-voltage detecting transistor Tₜₕ are to be formed (FIG. 4-3).

Next, a second conductive film, such as a metal, serving as a wiring is formed on the entire surface of the insulating layer 120 on which the channel layer 121 has been formed. The second conductive film is patterned into a predetermined shape by a photolithography technique and an etching technique to form the second wiring layer. The second wiring layer includes the image signal line 14, the upper electrode 133 of the storage capacitance Cₛ, a source electrode 132 and a drain electrode 131 of the threshold-voltage detecting transistor Tₜₕ, the wirings 134 to 136 for connecting the transistors and the wirings respectively, and a contact 138 for connecting the first wiring layer and the second wiring layer (FIG. 4-4). The second wiring layer is formed so as to fill the via holes 122.

The image signal line 14 extends in the y-axis direction so as to be formed above the shield electrode 113 with the width narrower than the width of the shield electrode 113. Here, it is preferable that the image signal line 14 settles within the shield electrode 113 when the pixel is viewed in the plane. The image signal line 14 is connected to the source electrode of the switching transistor Tₛ formed on the scanning line 13. The upper electrode 133 of the storage capacitance Cₛ is connected to the drain electrode of the switching transistor Tₛ, and also electrically connected to the drain electrode of the switching transistor Tₘ. The wiring 134 is patterned such that the source electrode of the switching transistor Tₘ is electrically connected to the power supply line 10. The wiring 135 is patterned such that the source electrode of the threshold-voltage detecting transistor Tₜₕ and the lower electrode 112 of the storage capacitance Cₛ are electrically connected. Further, the drain electrode is patterned so as to be connected to the cathode of the organic EL element OLED to be formed in the later process. The wiring 136 patterned such that the drain electrode of the drive transistor T_{d} is electrically connected to the power supply line 10, and the source electrode is patterned so as to be connected to the cathode of the organic EL element OLED (FIG. 2).

Then, the flattened film 140 composed of an insulating layer is formed on the second wiring layer. A via hold 141 that penetrates the flattened film 140 is formed, by a photolithography technique and an etching technique, at the portion where a third wiring layer to be formed later is electrically connected to the first wiring layer or the second wiring layer (FIG. 4-5). Thereafter, a third conductive film, such as a metal, serving as a wiring is formed, and then patterned into a predetermined shape with a photolithography technique or an etching technique so as to form the common electrode 151 to be the anode shared with the organic EL elements OLED to be formed later at the respective pixel areas (FIG. 4-6). Here, the common electrode 151 is electrically connected to the GND line 15 through the contact 138 formed on the second wiring layer at the connection area where the via hold 141 is formed. The organic EL element OLED is formed on the flattened film 140 on which the common electrode 151 have been formed by a known method. Thus, the image display device according to the one embodiment of the present invention is obtained.

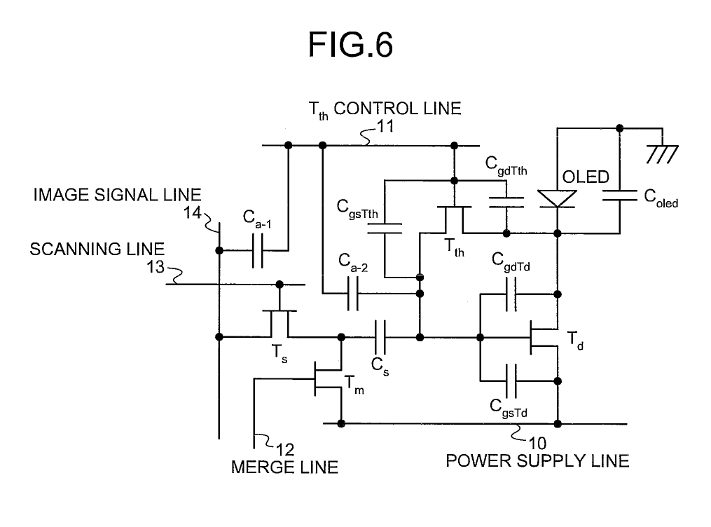

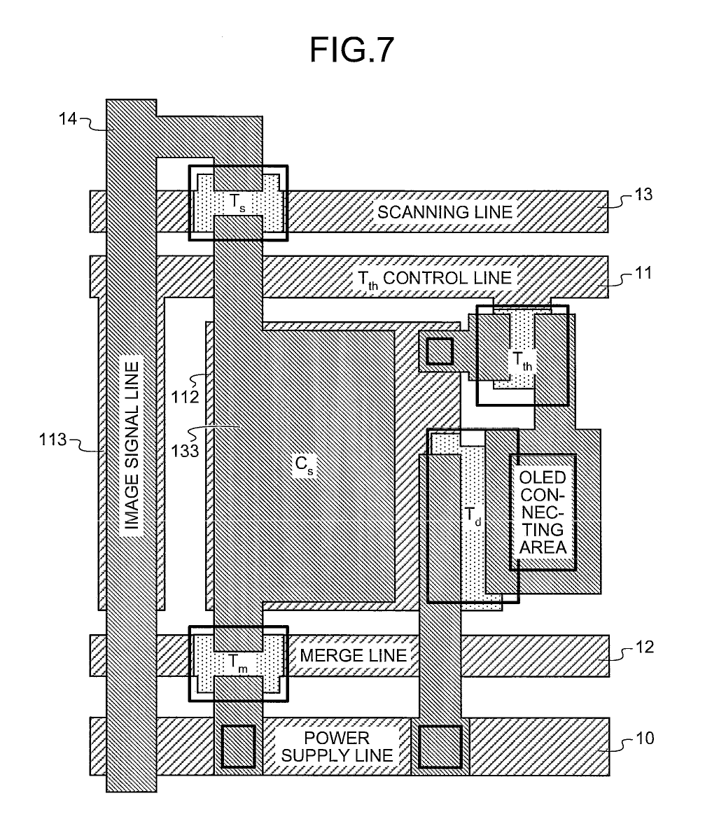

Although, in FIGS. 1 to 3, it is the case in which the shield electrode 113 is connected to the common electrode 151 (GND) of the organic EL element OLED, the shield electrode 113 that shields the electric field of the image signal line 14 may be connected to the wiring whose potential hardly varies during the each of the threshold-voltage detecting period and the light-emitting period as described above. FIG. 6 is a diagram illustrating another example of a configuration of a pixel circuit corresponding to one pixel of the image display device according to one embodiment of the present invention. FIG. 7 is a plan view of the pixel circuit in FIG. 6. FIGS. 6 and 7 illustrate the case in which the shield electrode 113 is connected to the Tₜₕ control line 11. As illustrated in the plan view of FIG. 7, the shield electrode 113 and the Tₜₕ control line 11 can be connected directly in this case, whereby the pixel area can be narrowed compared to the case in FIG. 2. Moreover, the shield electrode 113 can be connected to the other wiring whose potential is held substantially constant during each of the threshold-voltage detecting period and the light-emitting period.

According to the embodiment described above, the shield electrode 113 for shielding the electric field of the image signal line 14 is provided between the image signal line 14 and the storage capacitance Cₛ, and the shield electrode 113 is connected to the wiring whose potential hardly varies during each of the threshold-voltage detecting period and the light-emitting period of the own pixel area. As a result, the storage capacitance Cₛ is hardly affected by the signal of the other pixel flowing through the image signal line 14 during the threshold-voltage detecting period and the light-emitting period, and thereby crosstalk and ghost can be reduced to enhance the image quality.

1. An image display device comprising:
a plurality of pixels including a light-emitting element, a driver element that controls light emission of the light-emitting element, and a capacitive element electrically connected to the driver element; and
an image signal line that is commonly connected to the pixels for sequentially supplying, to the pixels, an image signal corresponding to luminous brightness of the light-emitting element, wherein
the pixel includes a shield electrode that shields an electric field from the image signal line to the capacitive element.

2. The image display device according to claim 1, wherein
the pixel further includes a threshold-voltage detecting element that detects a threshold voltage of the driver element by utilizing electrical charges accumulated in the capacitive element, and
the shield electrode is connected to a wiring to which a constant voltage is applied during a threshold-voltage detecting period of an own pixel by the threshold-voltage detecting element and during a light-emitting period for allowing the light-emitting element to emit light by a control of the driver element.

3. The image display device according to claim 2, wherein the shield electrode is connected to a wiring to which a constant voltage is applied from the threshold-voltage detecting period to the light-emitting period.

4. The image display device according to claim 3, wherein the wiring is a grounding wire that is retained to a ground potential from the threshold-voltage detecting period to the light-emitting period.

5. The image display device according to claim 1, wherein
the light-emitting element includes a common electrode which is shared by the pixels, and
the shield electrode is electrically connected to the common electrode.

6. The image display device according to claim 1, wherein the light-emitting element includes a luminescent layer made of an organic material.

7. An image display device comprising:
a plurality of pixels including a light-emitting element, and a capacitive element for accumulating electrical charges corresponding to luminous brightness of the light-emitting element; and
an image signal line that is commonly connected to the pixels, wherein
the pixel includes a shield electrode between the image signal line and the capacitive element.

8. The image display device according to claim 7, wherein the shield electrode is interposed between the capacitive element and the image signal line.

9. The image display device according to claim 7, wherein the shield electrode is provided apart from the image signal line, and immediately below the image signal line.

10. The image display device according to claim 7, wherein the width of the shield electrode is greater than the width of the image signal line.
